(19) United States
(12) Patent Application Publication
(10) Pub. No.: US 2012/0261644 A1
(43) Pub. Date: Oct. 18, 2012

(54) STRUCTURE AND METHOD OF MAKING GRAPHENE NANORIBBONS

(75) Inventor: Christos Dimitrakopoulos, Baldwin Place, NY (US)

(73) Assignee: INTERNATIONAL BUSINESS MACHINES CORPORATION, Armonk, NY (US)

(21) Appl. No.: 13/088,765

(22) Filed: Apr. 18, 2011

(51) Int. Cl. H01L 29/775; B32B 9/00; D04H 11/00; C23C 14/28; H01L 21/04; C01B 31/04; B32B 5/12; B82Y 30/00

(52) U.S. Cl. 257/29; 423/448; 428/367; 428/114; 428/93; 427/595; 438/151; 977/734; 257/E29.245; 257/E21.049

(57) ABSTRACT

Disclosed is a ribbon of graphene less than 3 nm wide, more preferably less than 1 nm wide. In a more preferred embodiment, there are multiple ribbons of graphene each with a width of one of the following dimensions: the length of 2 phenyl rings fused together, the length of 3 phenyl rings fused together, the length of 4 phenyl rings fused together, and the length of 5 phenyl rings fused together. In another preferred embodiment the edges of the ribbons are parallel to each other. In another preferred embodiment, the ribbons have at least one arm chair edge and may have wider widths.

The invention further comprises a method of making a ribbon of graphene comprising the steps of:
a. placing one or more polyaromatic hydrocarbon (PAH) precursors on a substrate;
b. applying UV light to the PAH until one or more intermolecular bonds are formed between adjacent PAH molecules; and
c. applying heat to the PAH molecules to increase the number of intermolecular bonds that are formed to create a ribbon of graphene.

The invention further comprises an electrical device structure having two or more ribbons of graphene in surface to surface contact with a non conductive substrate. Each of the ribbons has a width less than 3 nm and each of the ribbons has edges that are parallel to one another. In a preferred embodiment the ribbons comprise a channel in a Field Effect Transistor (FET).

### BACKGROUND OF THE INVENTION

1. Field of the Invention

This invention relates to graphene in a narrow ribbon structure and a method for making the same. More specifically, the invention relates to the use of graphene ribbons in electrical devices.

2. Brief Description of the Prior Art

Graphene is defined as a single layer of graphite with the carbon atoms occupying a two-dimensional (2D) hexagonal lattice. It has been used extensively in the past to model the electronic structure of carbon nanotubes (CNTs) [See R. Saito, G. Dresselhaus, M. S. Dresselhaus, Physical Properties of Carbon nanotubes, Imperial College Press, London, 1998; T Ando, Advances in Solid State Physics, Springer, Berlin, 1998, pp 1-18, S. Reich, C. Thomsen, J. Maultzsch “Carbon Nanotubes” Wiley-VCH, 2004 ISBN 3-527-40386-8]. Graphene is a 2D, zero-gap semiconductor that exhibits a linear relationship between the electronic energy E(p) and the 2D momentum p, i.e. E(p)=v₀ p, (where v₀ is the carrier velocity, p=η\sqrt{kₓ²+k_{y}²}, η is Planck's constant divided by 2π, and kₓ, and k_{y} are reciprocal space vectors in the x and y direction, respectively), instead of the quadratic energy-momentum relationship that describes the energy bands of common semiconductors [See C. Berger et. al., Science 312, 1191, (2006).]. This implies that the electron effective mass is zero and the charge carriers in graphene can be described as relativistic Dirac Fermions. Graphene layers with fairly large lateral dimensions have been produced either by exfoliation of graphite [KS. Novoselov et. al., Science 306, 666, (2004)], epitaxially on SiC by high temperature decomposition of the latter [C. Berger et al. J. Phys. Chem. B, 108, 19912, 2004], or by chemical vapor deposition (CVD) on metals. [Reina, A. et al. Large Area, Few-Layer Graphene Films on Arbitrary Substrates by Chemical Vapor Deposition. Nano Lett. 9, 30-35, (2009); Li X et al. Large-Area Synthesis of High-Quality and Uniform Graphene Films on Copper Foils Science 324, 1312-1314, (2009)]. Reported studies have revealed the remarkable transport properties of graphene [KS. Novoselov et. al., Nature (2005) 438, 197; Y. Zhang et. al., Nature (2005) 438, 201; C. Berger et. al., Science (2006) 312, 1191; MI. Katsnelson, Materials Today (2007) 10, 20] including electron and hole mobilities of the order of 2×10 cm /V.s, i.e. similar to those reported for single CNTs, or higher. However, in suspended graphene devices, the carrier mobility μ=(neρ)⁻¹, where n is the carrier density and ρ is the resistivity, can exceed 200,000 cm [See Bolotin, K. I. et al. Ultrahigh electron mobility in suspended graphene. Solid State Commun. 146, 351-355 (2008).]

Based on these properties, graphene is being considered for application as the active channel for field effect transistor (FET) applications. However, due to the fact that a macroscopic 2D sheet of graphene is a zero-band-gap semiconductor, it cannot be used in FET for digital, logic applications in its 2D form. A minimal conductivity of approximately e²/h (where e is the electron charge and h is Planck's constant) has been observed experimentally in both single and bilayer graphene [See K. S. Novoselov et. al., Nature (2005) 438, 197; MI. Katsnelson, Materials Today (2007) 10, 20]. This would make it impossible to create FETs with reasonable Iₒₙ/I_{off} ratios (i.e., on-off current ratios), as I_{off} would be too high.

Prior art has shown that a small band gap in the range of 100-250 meV can open in 2D graphene in special situations (e.g. by doping part of a graphene bilayer [T. Ohta, A. Bostwick, T. Seyller, K. Horn, E. Rotenberg, Science, 313, 951, (2006)], due to interaction with the substrate [Zhou S. Y. et al. Substrate-induced bandgap opening in epitaxial graphene Nature Mater. 6, 770, (2007)], or by applying an appropriate combination of antisymmetric electrical fields perpendicular to the plane of a graphene bilayer [Y. Zhang, et al. “Direct observation of a widely tunable bandgap in bilayer graphene,” Nature 459, 820 (2009)]). Band gap values in this range are probably too low for digital applications. Additionally, there are serious inherent problems with all these approaches, including that there is no good method to apply controlled doping in graphene; the choice of substrate cannot be made based solely on the need to open a band gap; the effect of substrate surface defects and non-uniformity on the properties of graphene is pronounced; In traditional field effect transistors, where the active layer is a semiconductor with a fixed band gap, the gate is used to modulate the carrier concentration in the channel, not to modulate the band gap of the semiconductor. Requiring a second role for the gate would seriously complicate or impede the performance of a graphene transistor.

Theoretical calculations have shown that narrow ribbons of graphene with widths ranging in the nanometer scale, defined as nanoribbons here, exhibit an energy band gap. This is because, electrons in graphene, besides their 2D confinement, are further confined by the narrow width of the nanoribbons. The latter confinement results in splitting of the original 2D energy levels of graphene making the graphene nanoribbons semiconductors with a finite energy gap. FIG. 1, is a plot of the band gap of a graphene ribbon vs. its lateral dimension (width, in nm), based on the equation:

$$Δ E ( W ) = \frac{{hv}_{0}}{2 W} = \frac{2.067 eV \cdot nm}{W}$$

$${v}_{0} = {10}^{15} nm \text{/} s$$

$$W in nm$$

### [See C. Berger et. al., Science (2006) 312, 1191].

FIG. 1 shows that if the width of a graphene ribbon is reduced sufficiently, the band gap is increased to values that would permit the fabrication and operation FET with good device characteristics. This would open the door to graphene FET applications.

Top down approaches for patterning a 2D graphene sheet into graphene nanoribbons from 2D graphene, with specific placement and orientation, for example using some kind of lithography (optical or electron beam lithography), are limited to minimum ribbon width sizes of about 30 nm for making an array of ribbons and in the easier case of an isolated feature just about 10 nm. At 30 nm graphene nanoribbon width the calculated band gap is less 0.1 eV and at 10 nm width it is about 0.2 eV. Using top-down graphene nanoribbon patterning, prior art has produced band gaps in the range of 30 meV [See Z. Chen et al. “Graphene nano-ribbon electronics” Physica E 40, 228, (2007)] to 200 meV [See M. Y. Han et al. “Energy Band-Gap Engineering of Graphene Nanoribbons” Phys. Rev. Lett. 98, 206805 (2007)]. These values are quite low compared to main stream semiconductors (e.g. the gaps of Si, Ge and GaAs are 1.12, 0.66, and 1.42 eV respectively) but in the range of energy band gaps of some low-band-gap compound semiconductors (e.g. InSb has a gap of 0.17 eV). [See S. M. Sze, Physics of Semiconductor Devices, 2nd edition, 1981, p. 849].

Methods of forming graphene nanoribbons by unzipping carbon nanotubes parallel to their long axis have recently been reported, and graphene nanoribbons narrower than 10 nm have been successfully fabricated. Tour et al. recently reported a solution-based oxidative process for producing oxidized graphene nanoribbon structures by lengthwise cutting and unraveling of multiwall carbon nanotube (MWCNT) side walls. [See D. V. Kosynkin et al. Nature 458 872 (2009)]. Then they reduced them to graphene nanoribbons. Dai et al. [See Li X. et al. Science 319, 1229 (2008)] exfoliated commercial expandable graphite (Grafguard 160-50N, Graftech Incorporated, Cleveland, Ohio) by heating to 1000° C. in forming gas (3% hydrogen in argon) for 60 seconds. The resulting exfoliated graphite was dispersed in a 1,2-dichloroethane (DCE) solution of poly (m-phenylenevinylene-co-2,5-dioctoxy-p-phenylenevinylene) (PmPV) by sonication for 30 min to form a homogeneous suspension. Centrifugation then removed large pieces of materials from the supernatant. Atomic force microscopy (AFM) was used to characterize the materials deposited on substrates from the supernatant and numerous Graphene Nanoribbons (GNRs) with various widths ranging from w˜50 nm down to sub-10 nm were observed. Topographic heights of the GNRs (average length˜1 micron) were mostly between 1 and 1.8 nm, which, according to the authors of that report correspond to a single layer or a few layers (mostly≦3 layers). [See Li X. et al. Science 319, 1229 (2008).]

To complicate things further, the crystallographic orientation of the edge of graphene nanoribbons determines if the latter is semiconducting or metallic. Specifically, if the long edge of a graphene nanoribbon has the “zigzag” structure, the layer does not have a band gap. On the other hand, if the long edge has an “armchair” structure the graphene nanoribbon is semiconducting. [See K. Nakada, M Fujita, G. Dresselhaus and M. S. Dresselhaus, Phys. Rev. B (1996) 54, 17954]. Furthermore, if the number of the repeating units, N, in the generally semiconducting armchair graphene nanoribbons has specific values, i.e. when N=3M−1, where M is an integer, the GNR is metallic. [See K Nakada, M Fujita, G. Dresselhaus and M. S. Dresselhaus, Phys. Rev. B (1996) 54, 17954].

All of the references cited herein are incorporated by reference in their entirety.

### Problems with the Prior Art

It is immediately apparent that both of these methods of creating sub-10 nm wide graphene nanoribbons have manufacturability issues. The Dai et al. method, produces a mixture of nanoribbon lengths and widths. The variation in width would produce a variety of band gaps in semiconducting nanoribbons. The Tour et al. method, probably produces nanoribbons with tighter width distribution as the width is controlled by the CNT diameter, but because MWCNTs are used, each layer would produce a different nanoribbon width even if a supply of MWCNT with very tightly controlled diameter were available. However, the prior art does not disclose the CNT diameter control necessary to produce nanoribbons with widths tightly controlled enough for industrial applications. Furthermore, the variety of directions that the unzipping of a CNT wall can take, as described in the relevant reference, would result to various graphene nanoribbon chiralities and edge structures. As we described above, changing the edge structure of a GNR with a specific width from “zigzag” to “armchair” can change the GNR electrical character from metallic to semiconducting, respectively. Thus, not having precise control over the GNR chirality and edge structure renders the GNR property unpredictable and thus not broadly applicable technologically.

None of the prior art, including Tour and Dai, disclose structures of graphene or methods of fabricating these structures with demonstrated control over the type, size (width and length), chirality, and edge structure of the nano ribbons. Further, none of the prior art has methods for producing one specific type of nano ribbon without producing other types. In addition, none of the prior art discloses a structure of two or more nano ribbons of the same type placed together. In addition, none of the prior art discloses straight nano ribbons of a specific type that are placed together.

Even though the prior art has randomly produced graphene nanoribbons of dimension below 9 nm in width, it has failed to disclose nanoribbons with a specific band gap. Further, the band gaps disclosed in random samples in the prior art are randomly distributed and thus it is difficult, expensive, impractical, or impossible to produce structures useful in electrical devices from such samples. One reason for this is that the prior art can not produce structures that are uniform in shape, size, straightness, and chirality; have uniform band gaps; or have predictable placement or orientation. The prior art does not disclose two or more nanoribbons placed together with the same band gap within a given tolerance. This fatal shortcoming prevents use of the prior art in large scale production of electric devices using graphene nanoribbons.

Both methods would suffer strongly from uncertainty of placement of GNRs on a substrate, since a solution method is used. This randomness, does not offer any improvement over the problems of predictably placing CNTs on a substrate, and thus there would be no reason to use GNRs instead of CNTs for electronics applications. Furthermore, graphene nanoribbons produced in these prior-art described ways, cannot directly benefit from recent progress of controlled placement of CNTs.

This clearly shows that due to the small width required to reach large enough band gaps to create FETs with reasonable device characteristics, and, equally importantly, the interatomic bond dimension level accuracy and control required for creating the appropriate edge structures of the nanoribbons in order to make them semiconducting, top-down approaches for creating graphene nanoribbons will fail to produce the required structures for electrical devices, e.g. FETs or diodes. Currently this prediction is shown to be true.

“Atomically precise bottom-up fabrication of graphene nanoribbons” by Jinming Cai et al. [Cal J. et al Nature 466, 470, (2010)] discloses a structure and method for fabricating graphene nanoribbons by surface assisted coupling of molecular precursors into polyphenylenes and subsequent cyclodehyrogenation. The reference used a 10,10′-dibromo-9,9′-bianthryl precursor monomer to create ordered rows of this molecule on a metal surface an then polymerize the molecules by heating to form graphene nanoribbons. However, the Cai reference uses a bianthryl molecule with a rotationally flexible covalent bond which creates a non-rigid molecule with many possible conformations on the substrate surface. Therefore, the Cai reference method has difficulty creating a multitude of parallel ribbons with certainty. Inspection of FIG. 2 of this reference shows that many of the ribbons on the substrate are in random orientations.

### Aspects of the Invention

An aspect of this invention is a structure and a method to produce a structure of one or more graphene ribbons that are uniform in shape, size, straightness, and/or chirality; have uniform band gaps; and/or have predictable placement or orientation.

An aspect of this invention is a graphene ribbon structure less than 9 nm wide, more preferably less than 1.6 nm wide.

A further aspect of this invention is a graphene ribbon structure that is five fused aromatic rings or less in width fused together in a ribbon length.

A further aspect of this invention is a graphene ribbon structure that is five aromatic rings or less in width fused in a length direction with a width tolerance of less than 0.5 nm in variation, more preferably less than 0.1 nm in variation.

A further aspect of this invention is a graphene ribbon structure that is five aromatic rings or less in width fused in a length direction and has “arm chair” edges.

A further aspect of this invention is a graphene ribbon structure that is five aromatic rings or less in width fused in a length direction that has “arm chair” edges and with a width tolerance of less than 0.5 nm in variation, more preferably less than 0.1 nm in variation.

An aspect of this invention is a graphene ribbon structure less than 9 nm wide, more preferably less than 1.6 nm wide with a predictable placement on a substrate.

An aspect of this invention is a graphene ribbon structure less than 9 nm wide, more preferably less than 1.6 nm wide with a predictable orientation on a substrate.

An aspect of this invention is a graphene ribbon structure less than 9 nm wide, more preferably less than 1.6 nm wide with a predictable orientation on a substrate where the orientation is related to a crystal orientation of the substrate.

An aspect of this invention is a graphene ribbon structure less than 9 nm wide, more preferably less than 1.6 nm wide, that is connected to one or more conductive electrodes using standard patterning techniques, e.g. lithography.

An aspect of this invention is a graphene ribbon structure less than 9 nm wide, more preferably less than 1.6 nm wide, which is used in an electronic device, e.g. an FET or diode.

An aspect of this invention is a graphene ribbon structure less than 9 nm wide, more preferably less than 1.6 nm wide, which is used in a channel region of an electronic device, e.g. an FET.

An aspect of this invention is multiple graphene ribbon structures less than 9 nm wide each, more preferably less than 1.6 nm wide each, which are used in a channel region of an electronic device, e.g. an FET.

An aspect of this invention is multiple graphene ribbon structures less than 9 nm wide each, more preferably less than 1.6 nm wide each, which are layered and used in a channel region of an electronic device, e.g. an FET.

A further aspect of this invention is a graphene ribbon structure that is five fused aromatic rings in width with a width tolerance of less than 0.5 nm in variation, more preferably less than 0.1 nm in variation that uses pentacene molecules as the molecular building block.

A further aspect of this invention is a graphene ribbon structure that is four fused aromatic rings in width with a width tolerance of less than 0.5 nm in variation, more preferably less than 0.1 nm in variation that uses tetracene molecules as the molecular building block.

### SUMMARY OF THE INVENTION

The present invention is a ribbon of graphene less than 3 nm wide, more preferably less than 1 nm wide. In a more preferred embodiment, there are multiple ribbons of graphene each with a width of one of the following dimensions: the length of 2 phenyl rings fused together, the length of 3 phenyl rings fused together, the length of 4 phenyl rings fused together, and the length of 5 phenyl rings fused together. In another preferred embodiment the edges of the ribbons are parallel to each other. In another preferred embodiment, the ribbons have at least one arm chair edge and may have wider widths.

The invention further comprises a method of making a ribbon of graphene comprising the steps of:
a. placing one or more polyaromatic hydrocarbon (PAH) precursors on a substrate;
b. applying UV light to the PAH until one or more intermolecular bonds are formed between adjacent PAH molecules; and
c. applying heat to the PAH molecules to increase the number of intermolecular bonds that are formed to create a ribbon of graphene.

The invention further comprises an electrical device structure having two or more ribbons of graphene in surface to surface contact with a non conductive substrate. Each of the ribbons has a width less than 3 nm and each of the ribbons has edges that are parallel to one another. In a preferred embodiment the ribbons comprise a channel in a Field Effect Transistor (FET).

### BRIEF DESCRIPTION OF THE FIGURES

FIG. 1 is a graph of a function in the prior art that shows band gap energy versus GNR width.

FIG. 2A is a prior image showing the alignment of pentacene molecules on a gold substrate.

FIG. 2B is a prior image showing the alignment of pentacene molecules on a gold substrate.

FIG. 3 shows a schematic of a prior art array of pentacene molecules aligned side by side as in FIG. 2.

FIG. 4 is a schematic of novel array of pentacene molecules aligned side by side chemically interconnected to prevent volatilization.

FIG. 5A is a schematic of a novel graphene nanoribbon (GNR) less than 3 nanometers wide with armchair long edges that is produced by heating and/or radiating the structure of FIG. 4.

FIG. 5B shows a sequence of three novel structures (first a row of tetracene molecules, second tetracene molecules aligned side by side chemically interconnected to prevent volatilization, and third a novel graphene nanoribbon (GNR) less than 2 nanometers wide with armchair long edges produced from the tetracene chemically interconnected structure (540).

FIG. 5C shows a sequence of three novel structures (first a row of anthracene molecules, second anthracene molecules aligned side by side chemically interconnected to prevent volatilization, and third a novel graphene nanoribbon (GNR) less than 1.5 nanometers wide with armchair long edges produced from the anthracene chemically interconnected structure (580).

FIG. 6 is a schematic of a novel process for producing graphene nanoribbon less than 3 nanometers wide with armchair long edges.

FIG. 7 is a block diagram of an apparatus used in the production of graphene nanoribbons.

FIG. 8, comprising FIGS. 8A through 8E, discloses structures made during the steps of making an FET with a GNR channel of the present invention.

FIG. 9 discloses the steps of a process that makes an FET with a GNR channel of the present invention.

FIG. 10 is a prior art table disclosing bond dissociation energies for carbon-carbon double bonds and carbon-hydrogen bonds.

FIG. 11 is a prior art graph of the ultra violet (UV) spectrum emitted by mercury (Hg) lamp.

### DETAILED DESCRIPTION OF THE INVENTION

Therefore, the present invention is a bottom-up approach, i.e. one where the graphene nanoribbons are constructed by using methods for self-assembly of appropriate molecules to make ordered rows of such molecules on appropriate substrate surfaces. The appropriate molecules (preferably anthracene, tetracene, pentacene) are chemically changed while assembled in flat-lying rows on a substrate into aromatic macromolecules with reduced volatility. In a preferred embodiment the chemical aromatic macromolecules are created by energetic beams (e.g. electromagnetic radiation, for example UV light, X-rays or e-beam or other radiation) or plasma that would cause the chemical change before the appropriate precursor molecules evaporate or sublime. The aromatic macromolecules are further converted to form graphene nanoribbons by a combination of heat and/or radiation. Since the aromatic macromolecule has a higher molecular weight the aromatic macromolecule is not volatile and can absorb the higher heat and/or radiation without subliming/evaporating before it converts into graphene nanoribbons (GNR). These GNRs have a width and edge structure accurately defined by the chemical structure of the original (precursor) molecule and the geometric structure of the ordered rows of the flat-lying “acene” precursor molecules.

Furthermore, unlike CNTs, where periodic boundary conditions are present, GNRs have edges with localized states [10] that can also affect transport. As very narrow GNRs are needed to achieve a band gap usable for FET applications for logic, the effect of the edges can be critical. Theoretical calculations have shown that when different hetero-atoms occupy are attached, or occupy edge positions in a graphene nanoribbon lattice, the transport properties of the various graphene nanoribbons are substantially affected. Thus, controlling the chemistry of the long edge of a graphene nanoribbon is very desirable. Here too, the prior top-down approaches do not offer the precision and selectivity of placing specific atoms at specific edge sites of a top-down fabricated graphene nanoribbon. On the other hand, the bottom-up approach proposed in this disclosure is very appropriate for doing exactly that. Starting with an appropriately functionalized molecule, i.e. the monomer (preferably acene molecules) from which the nanoribbon is created after polymerization (making the aromatic macromolecule), an appropriate edge functionalization of the graphene nanoribbon can be created, by specifically synthesizing the precursor molecules to comprise the desired atoms at its long ends.

Therefore, by using the preferred acene molecules (shown in Figures as elements 300, 530, and 560) the created graphene has the desired hydrogen termination at both the long edges and ends of the GNR in addition to the desired “arm chair” edge structure. Further, the precursor acene molecules could be modified by adding appropriate atoms other than hydrogen at the ends of the molecule creating acene derivative molecules. Alternatively, these acene derivative molecules could be used to create GNR using this disclosure where the GNR long edge will have the “arm chair” structure but with terminal atoms other than hydrogen. For example, GNR created with acene derivative molecules with Bromine (Chlorine, Nitrogen, etc.) bound to the ends of the acene molecules will produce GNRs with Bromine (etc.,) terminations on the long edges. Doing this could create electrical properties (e.g., electron mobilities) in the GNR that are different and/or superior to those GNR created by top down approaches or using this approach with acene precursors. Potentially, using acene derivative molecules as precursors could create electron mobilities as high as two dimensional graphene.

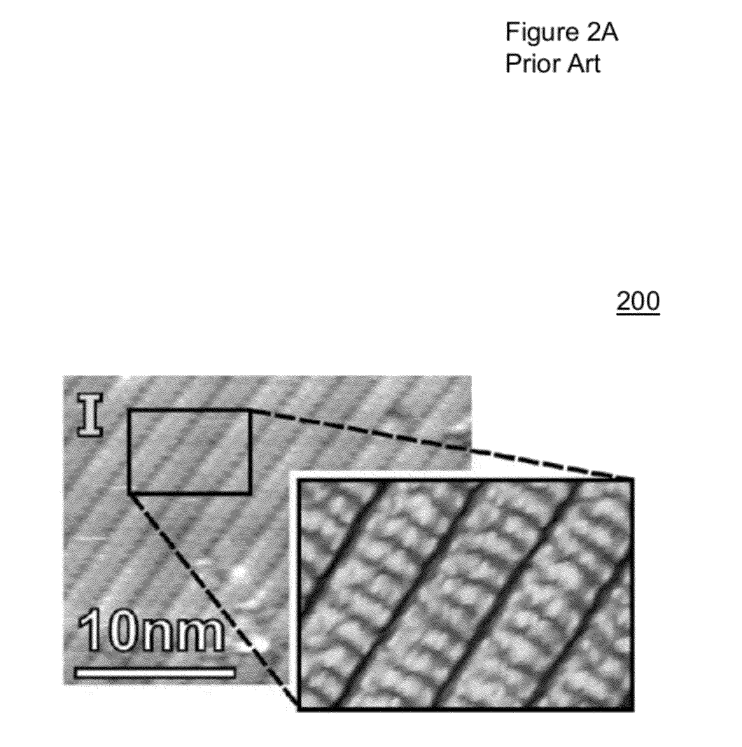

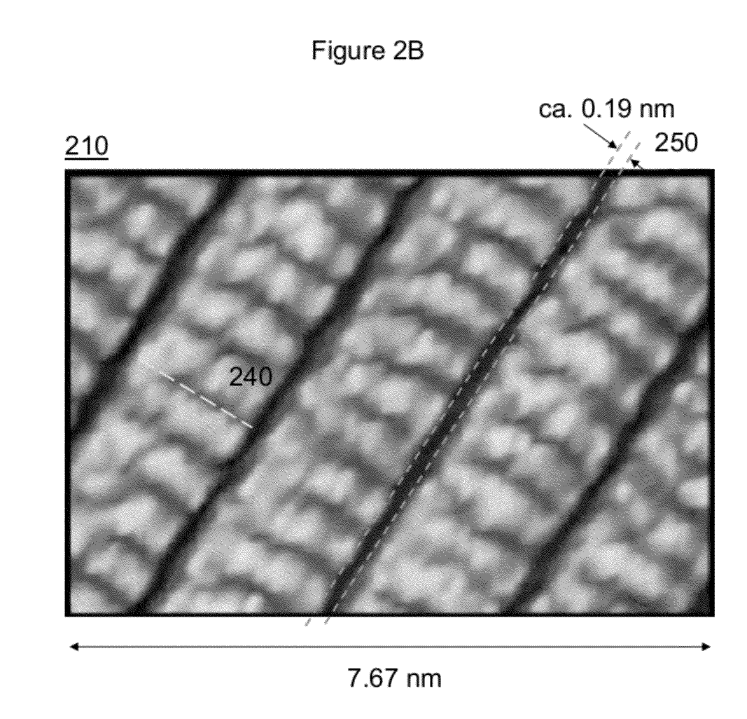

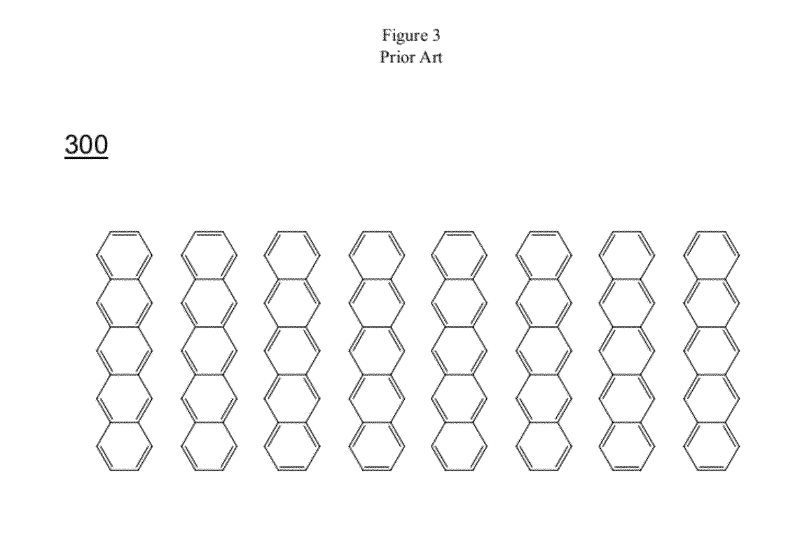

FIG. 2A is a prior image showing the alignment of pentacene molecules on a gold substrate. FIG. 2A shows that pentacene molecules, which have a length just above 1.5 nm, can grow parallel rows of the same width separated by a narrow gap from a nearest neighbor (nn) row on appropriate surfaces. The pentacene molecules lie with their long axis practically parallel to the surface and practically perpendicular to the direction of the strip, as shown in the prior art [Käfer D. et al. Phys.Rev. B 75, 085309 (2007)].

While FIG. 2A shows pentacene molecules self-assembled and flat lying on a Au (111) surface. However, the prior does not recognize or disclose the uses or advantages of flat lying pentacene to make aromatic macromolecules. Further, the prior art does not disclose or recognize the dimensional requirements in the placement of the pentacene molecules to produce an aromatic macromolecule.

FIG. 2B is a prior image 210 showing the alignment of pentacene molecules on a gold substrate.

FIG. 2B identifies dimensions of pentacene molecules shown in FIG. 2A that should be required to create aromatic macromolecules. Specifically, the gap distance 240 between the nearest neighbor (nn) atoms of adjacent pentacene molecules needs to be close enough so that if both nearest neighbor bonds are broken, a chemical bond between the two nn carbon atoms of the adjacent pentacene molecules at that point in the molecules can form. In a preferred embodiment, the van der Waals surfaces of these nn molecules are touching. This happens to be the case in FIG. 2B as shown by line 240 in the Figure. In addition, for a GNR with regular arm chair long edges to form, the row distance 250 between the nearest neighbor (nn) atoms of adjacent pentacene molecular rows needs to be large enough so that if the nearest neighbor hydrogen atom bonds are removed between the rows, no chemical bond can be created between the two nn carbon atoms of the pentacene molecules in such adjacent rows. In a preferred embodiment, the row distance 250 is about 2 Å, more preferable 0.19 nm. It so happens that this is also the case in FIG. 2A because of the distance between molecules in nn rows, row distance 250, is larger than the intermolecular distance 240 within the same row. This is forced by the epitaxial relation of the acene rows with the substrate surface, here Au (111). This prevents inter-row polymerization, which would result in two-dimension graphene formation. Therefore, gold (Au) is a preferred substrate on which to lay the acene molecule precursor because the intermolecular distance 240 is practically zero while the row distance 250 is approximately 2 Å due to the epitaxial relation of acene precursor molecules to gold. As mentioned below, other substrates are contemplated as long as these criteria are maintained.

Furthermore, we have added dashed lines, one 240 to indicate intermolecular distance within a row and two others 250 to show the row distance, distance between rows. These distances and restrictions not recognized in the prior art for the purposes of forming aromatic macromolecules. The lines 250 show the clearly existing gap between the van der Waals surfaces of molecules in two nn rows of pentacene (an acene precursor) molecules. We calculate that this gap is about 2 Å. On the other hand, the same image shows that there is no gap 240 between the van der Waals surfaces of such pentacene molecules in the same row. Thus, reaction between molecules in the same row is bound to happen when C—H bond are broken by appropriate energetic radiation, thus initiating the polymerization along a single row of pentacene molecules. Reaction is not expected to happen between molecules in nn rows, due to the gap of 2 Å, row distance 250 that exists between their van der Waals surfaces.

Note that substrates other than gold may be selected to achieve the purposes of this disclosure so long as the substrates can: 1. cause the precursor molecules to lie flat in row, 2. the row distance 250 is large enough to prevent inter-row polymerization, and 3. the intermolecular gap distance 240 between the nn precursor molecules within a row is small enough to create a bond between the precursor molecules. Examples of alternative substrates would be ones with a surface reconstruction that creates a unique orientation on the substrate, for example, silicon (110) and silicon (100) surface reconstruction creating dimer rows. There are many other (110) and (100) surfaces that could be used, e.g., copper (110). Further, these substrates can not form covalent bonds with the precursor molecules.

In addition, insulating substrates are contemplated which have a dimer row surface reconstruction. These surfaces have long range order reconstructions that would yield very long GNRs. An example of an insulator would be silicon carbide.

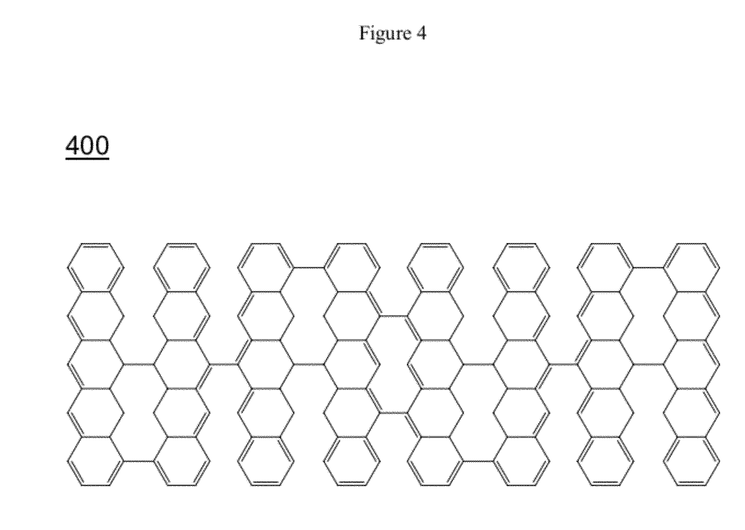

FIG. 3 shows a schematic of a prior art array of pentacene molecules aligned side by side as in FIG. 2A.

FIG. 3 further shows the optional pentacene derivative precursor molecules. In the Figure, Bromine atoms (not shown) would be optionally added at the ends of the pentacene molecules. Note that if no Bromine atoms are added, FIG. 3 shows pentacene molecules with the normal hydrogen atoms at the ends. Alternatively, some of the Bromine atoms can be replaced with other elements or functional groups that form single covalent bonds with carbon, such as Chlorine, Fluorine, other elements from the halogen family, NH4, OH, etc.

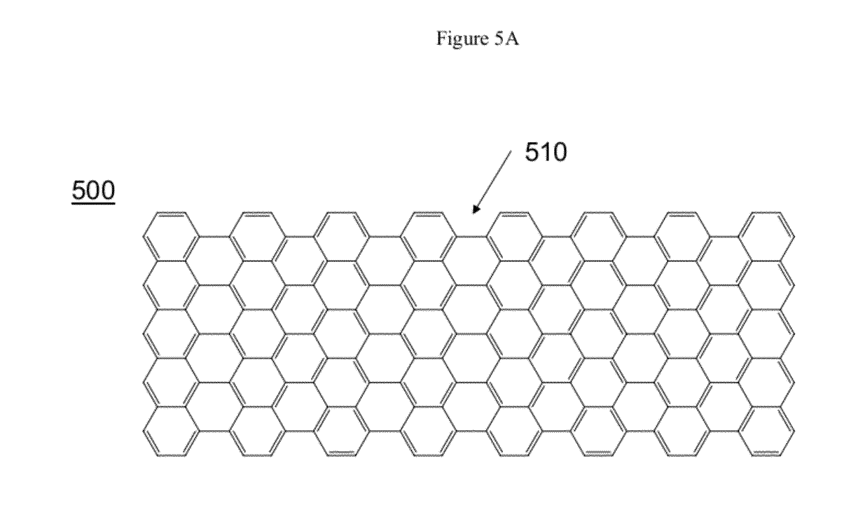

FIG. 4 is a schematic of novel array of pentacene molecules aligned side by side chemically interconnected to prevent volatilization.

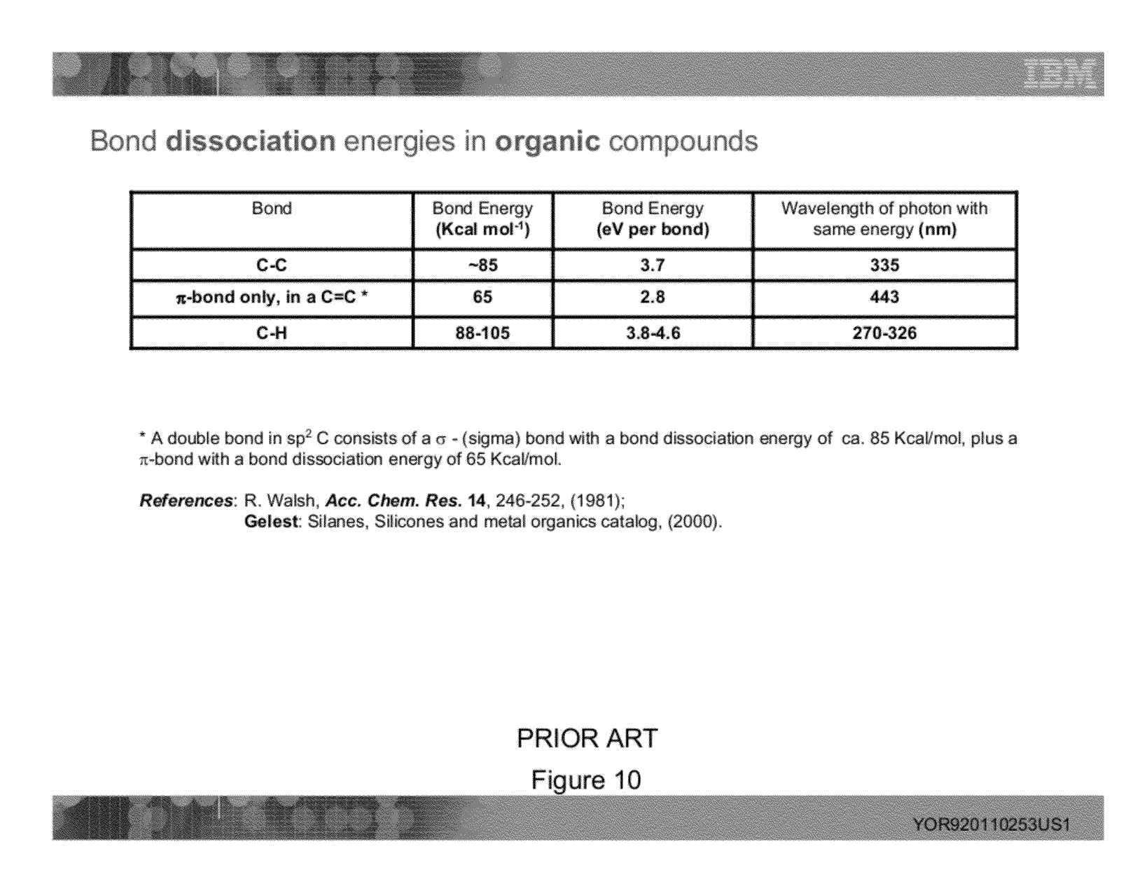

It is important that at least one bond between nn acene molecules within the same row is formed. This is done by applying radiation as with enough energy to dissociate C—H bonds for dehydrogenation and subsequent formation of C—C bonds between nn molecules in the same molecular row. In a preferred embodiment, the radiation applied has an energy spectrum that includes wavelengths shorter that visual light (e.g. ultraviolet radiation, x-ray radiation, electron beam or gamma rays). In a more preferred embodiment, UV light is used with a wave length between 250 and 350 nanometers. This range is selected based on the dissociation energy of the C—H bonds, which is between 3.8 and 4.6 eV (wavelength of 326-270 nm) according to the Table in FIG. 10. (The references for FIG. 10 are R. Walsh, Ace. Chem. Res. 14, 246-252, (1981) and Gelest: Silanes, Silicones and metal organics catalog, (2000).)

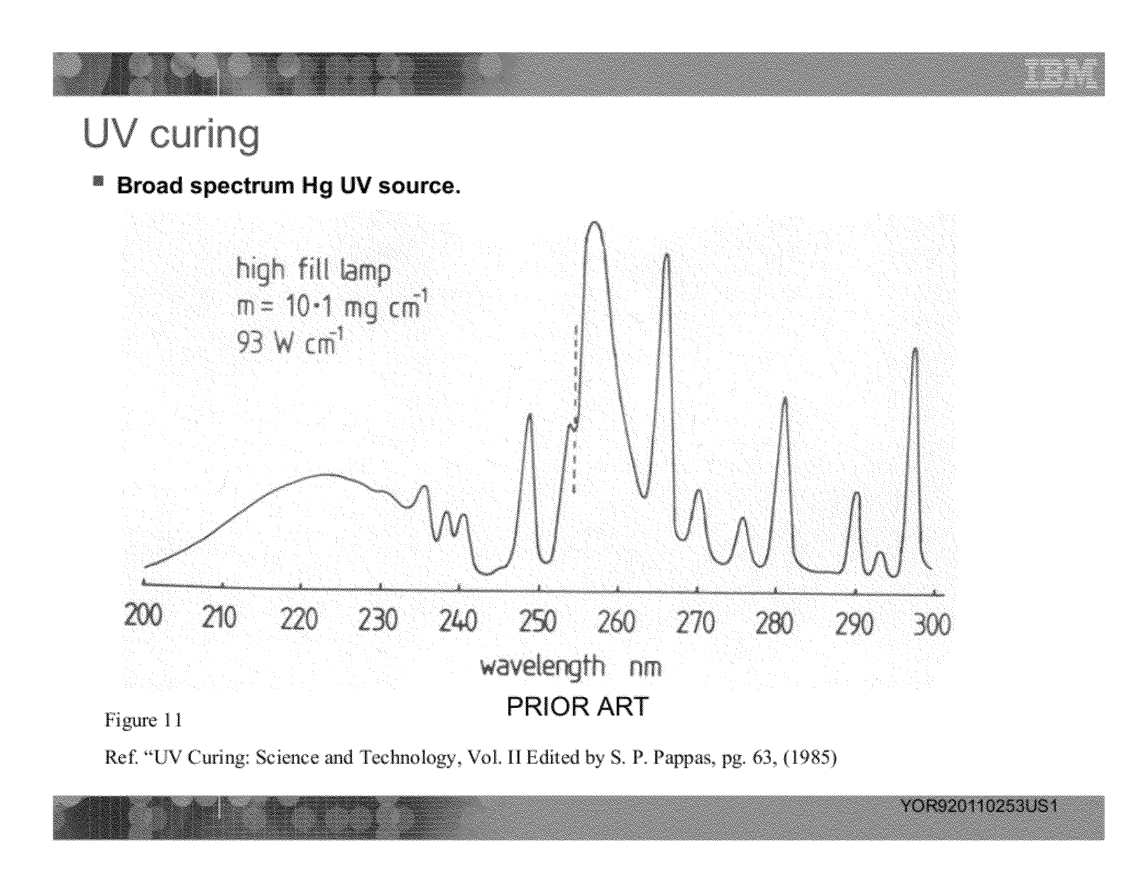

In a more preferred embodiment, UV light from a mercury (Hg) light source is used. A representative energy spectrum produced by such a source is shown in FIG. 11. (The reference for FIG. 11 is “UV Curing: Science and Technology, Vol. II Edited by S. P. Pappas, page 63, 1985.) Expected times of radiation exposure should be from 1 to 45 minutes. Alternatively, the sample is irradiated by a flood electron beam, under conditions similar to the ones described in prior art, i.e. e-beam energy in the range of 2 keV, beam current in the range of 1 mA, and the total dose from 100 to 1000 μC/cm² (reference: “Evaluation of Device Damage from e-Beam Curing of Ultra Low-k BEOL Dielectrics”, S. Mehta, C. Dimitrakopoulos, R. Augur, J. Gambino, A. Chou, T. Hook, B. Linder, W. Tseng, R. Bolam, D. Harmon, D. Massey, S. Gates, H. Nye, Proceedings of the Advanced Metallization Conference 2005 (AMC 2005), Editors: S. H. Brongersma, T. C. Taylor, M. Tsujimura, K. Masu, Pub. MRS, Warrendale, Pa., Volume V-21, pp. 261-267, (2006)).

The exposure of the ordered acene monolayer has to take place at a temperature that is well below the sublimation temperature of the specific acene in vacuum. By creating the intermolecular bonds (at least one for each nn molecule pair) between molecules within the same molecular row, a macromolecule is created whose sublimation temperature increases proportionally to each size. Thus, we subsequently raise the temperature (optionally with simultaneous irradiation with the chosen type of radiation) without the possibility of sublimation of the molecules and destruction of the molecular rows. When the temperature is high enough, dehydrogenation (dissociation of C—H bonds and removal of H atoms that sublime into the vacuum chamber) takes place, leaving behind dangling bonds of C, that eventually lead to formation of covalent C—C bonds between nn acene molecules. This is a consequence of the high energy state of two dangling bonds in nn sites compared to the formation of a new C—C bond. At even higher annealing temperatures, approaching 1000° C. but below the melting point of the substrate (e.g. Au), further dehydrogenation and the formation of the sp² structure typical of graphene will take place, as this is a favored and very stable state, energetically. Prior art provides numerous examples of graphitization and the stability of the formed graphitic species at temperatures between 700 and 1000° C.

As shown in FIG. 2B, the gap distance 240 between the nearest neighbor (nn) atoms of adjacent acene molecules needs to be close enough so that when both nearest neighbor bonds are broken, a chemical bond between the two nn carbon atoms of the adjacent pentacene molecules at that point in the molecules can form. In a preferred embodiment, the van der Waals surfaces of these nn molecules are touching. This happens to be the case in FIG. 2B as shown by line 240 in the Figure. In addition, for a GNR with regular arm chair long edges to form, the row distance 250 between the nearest neighbor (nn) atoms of adjacent acene molecular rows needs to be large enough so that if the nn hydrogen-carbon atom bonds between the rows are dissociated and hydrogen is removed, no chemical bond can be created between the two nn carbon atoms of the acene molecules in such adjacent rows. In a preferred embodiment, the row distance 250 is about 2 Å, or more. It so happens that this is also the case in FIG. 2A because the distance between molecules in nn rows, row distance 250, is larger than the intermolecular distance 240 within the same row. This is forced by the epitaxial relation of the acene rows with the substrate surface, here Au (111). This prevents inter-row polymerization.

It is possible that some C=C and C—C bonds in the sp² structure of an acene molecule will also be broken by impinging photons during the radiation treatment of the acene layer (either at room temperature or higher temperatures). However, carbon atoms are not volatile even at temperatures much higher that 1000° C. (e.g. 1500° C.). Thus, C atoms, even if their C—C bond to a nn C atom is broken, they remain in place on the substrate, and thus they have all the time necessary to reform such C—C bonds and eventually the energetically favored sp² structure of graphene. Obviously, this is not the case with the H atoms, which are volatile even at room temperature, immediately after a C—H bond is broken. This ensures that intermolecular C to C bonds (and eventually sp² structure) will be formed while intramolecular C to C bonds are preserved, despite the fact they may be broken temporarily and reformed. Thus, since the kinetics allow it (long time available), eventually the energetically sp² structure will form, creating the desired GNRs using a bottom-up fabrication scheme.

After long irradiation at a temperature below the sublimation point of the specific acene molecules used in the specific process (can be room temperature), which ensures formation of at least one bond for each nn pair of molecules within the same molecular row, the temperature is ramped up to promote further dehydrogenation and eventually sp² structure formation at temperatures approaching 1000° C. The ramp rate may vary between 10° C. per minute and 200° C. per minute, followed by anneal at a specific elevated temperature, between 500 and 1000° C., preferably 1000° C.

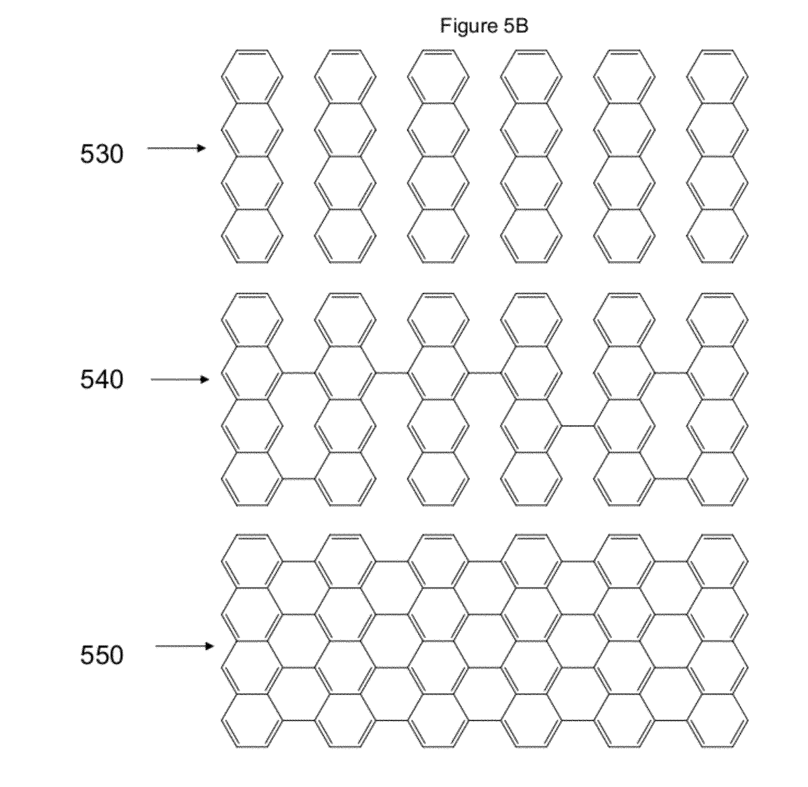

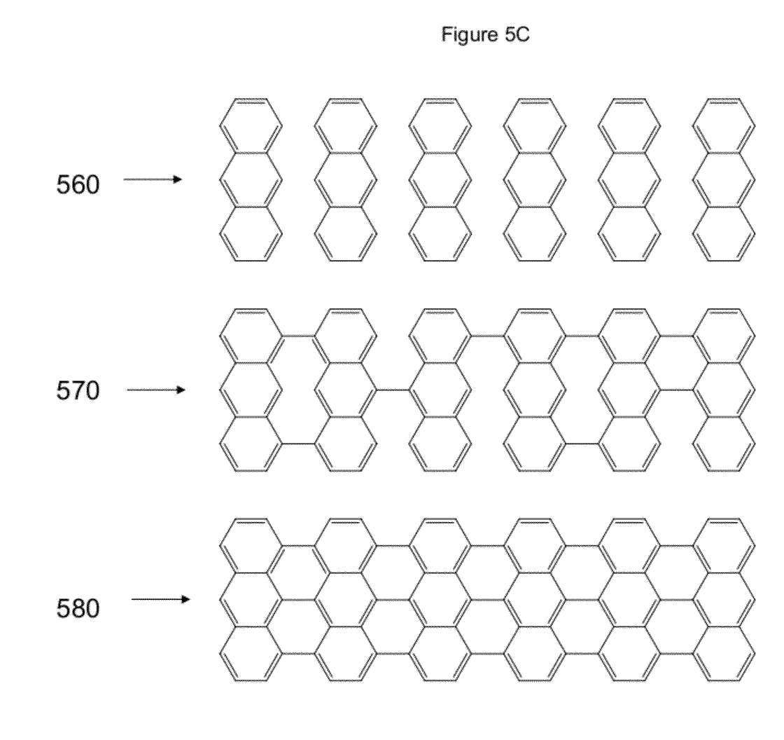

FIG. 5A is a schematic of a novel graphene nanoribbon (GNR) less than 3 nanometers wide with armchair long edges that is produced by heating, and preferably in addition irradiating the structure of FIG. 4 with UV light.

FIG. 5B shows a sequence of three novel structures (first a row of tetracene molecules, second tetracene molecules aligned side by side chemically interconnected to prevent volatilization, and third a novel graphene nanoribbon (GNR) less than 2 nanometers wide with armchair long edges produced from the tetracene chemically interconnected structure (540).

FIG. 5C shows a sequence of three novel structures (first a row of anthracene molecules, second anthracene molecules aligned side by side chemically interconnected to prevent volatilization, and third a novel graphene nanoribbon (GNR) less than 1.5 nanometers wide with armchair long edges produced from the anthracene chemically interconnected structure (580).

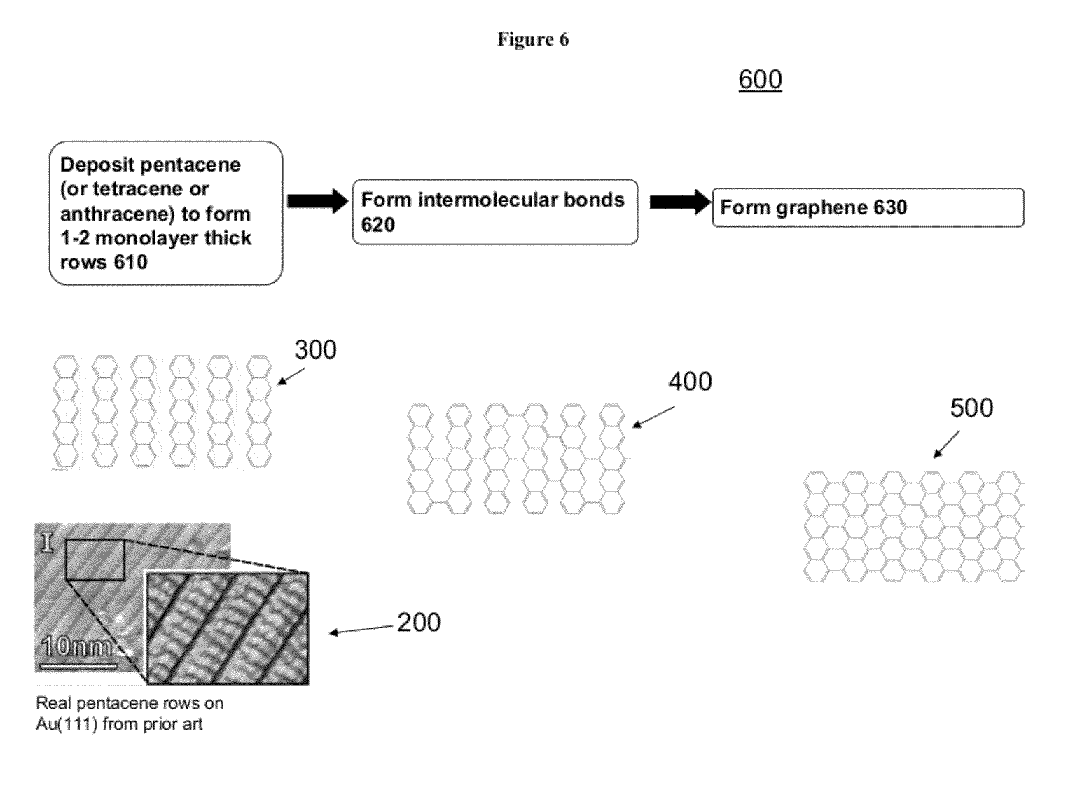

FIG. 6 is a schematic of a novel process for producing graphene nanoribbon less than 3 nanometers wide with armchair long edges.

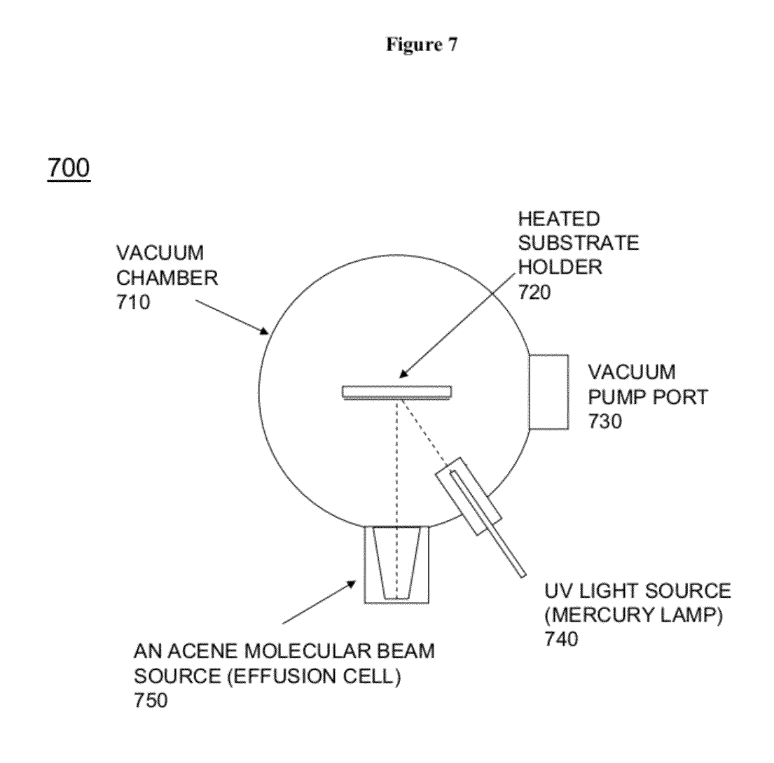

The process 600 begins by depositing 610 an acene precursor layer on a substrate that cause the acene precursor molecules to assemble in rows, as shown in FIG. 2A. As stated above, gold (111) is a preferred substrate, as are substrates with dimer row surface reconstruction. As mentioned above, preferred acene molecules include anthracene, tetracene, and pentacene. Preferred methods of deposition include heating the acene precursors in an apparatus as shown in FIG. 7 in a vacuum environment so that the precursors sublime into a gaseous state creating a molecular beam of the precursors. This molecular beam is directed toward the substrate where precursors are deposited (e.g., by condensation) on the substrate. In a preferred embodiment, the deposition is terminated once a monolayer is completed. There may be areas on the substrate where the thickness is 2 monolayers. Thickness monitors well known in the art, e.g., quartz crystal thickness monitors (QCM), are used to establish the thickness endpoint and termination of the deposition. The QCM will be calibrated using known surface science techniques to accurately determine the monolayer coverage. Vacuums preferable would be below 1E-9 Torr. Vacuums below this level insure that the substrate remains clean throughout the deposition.

As stated above, the acene precursor will align in rows 300 with intermolecular distances 240 that are near zero and row distances 250 of about 2 Å because of the epitaxial relation of the precursor molecules to the substrate.

The next step 620 is forming at least one bond between nn acene molecules within the same row. This is done by applying radiation as describe above in the description of FIG. 4. In a preferred embodiment, the radiation applied has energy above visual light. In a more preferred embodiment, UV light is used with a wave length between 250 and 350 nanometers. In a more preferred embodiment, UV light from a Hg light source is used. Expected times of radiation exposure should be from 1 to 45 minutes.

In step 630, graphene is formed by changing the macromolecule 400 formed in step 620 by adding heat. Since a macromolecule 400 was formed in step 620, the addition of heat will not volatilize the molecule before it is de-hydrogenated to form the GNRs 500. The amount of heat applies preferably is between 250 degrees ° C. but below the melting point of the substrate (e.g. gold layer). Pure gold has a melting point of 1064° C. The heat could be applied from 10 minutes to 10 hours with optimal times determined by experimentation, in an oxygen free atmosphere. In a preferred embodiment, the radiation applied in step 620 will continue throughout the heat application in step 630. The heat preferably will be applied in the vacuum chamber of FIG. 7 to promote de-hydrogenation and formation of the sp² structure of the carbon-carbon bonds to form the GNRs 500.

FIG. 7 is a block diagram of an apparatus 700 used in the production of graphene nanoribbons.

The apparatus 700 comprises a known vacuum chamber 710 for general deposition of materials on substrates. These vacuum chambers 710 are well known and can be purchase as a complete unit or in components for assembly. The vacuum chambers 710 are normally evacuated by vacuum pumps (not shown) through the vacuum pump port 730. The vacuum pumps can be one turbo pump and one mechanical pump in series configuration and optionally can include an ion pump and a titanium sublimation pump.

The chamber apparatus 700 comprises a heated substrate holder 720, e.g. a polymeric boron nitride/pyrolytic graphite heater commonly available for this purpose.

The chamber apparatus 700 further comprises a molecular source 750 that can be an effusion cell 750 that is commonly known.

The chamber apparatus 700 further novelty comprises a radiation source 740 that is used to apply radiation, preferably UV light, through a window that is transparent at the spectrum frequencies necessary for breaking carbon-hydrogen bonds. In a preferred embodiment, the window is made from quartz and the radiation source is a mercury (Hg) lamp that will produce the spectrum shown in FIG. 11.

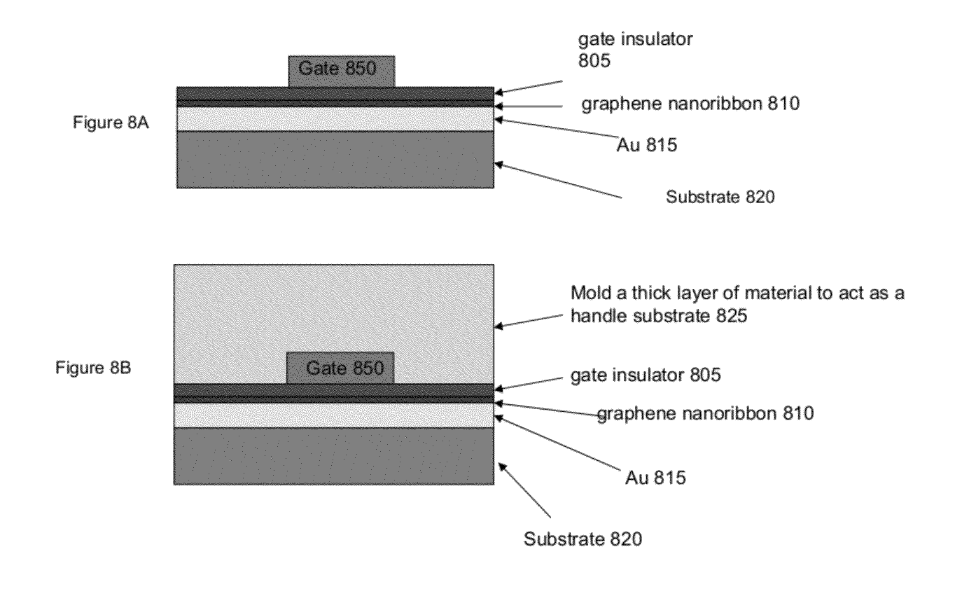

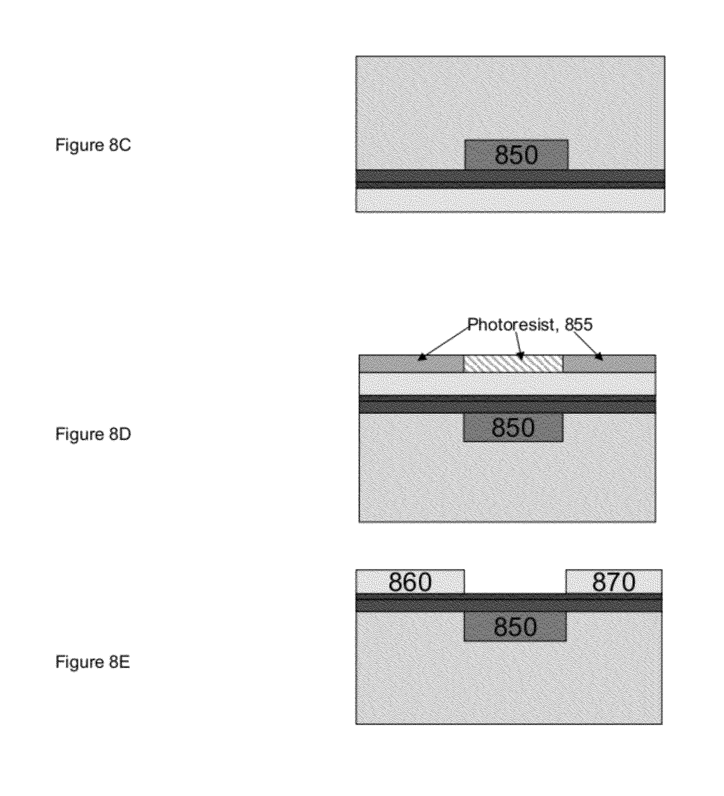

FIG. 8, comprises FIGS. 8A through 8E and discloses structures made during the steps of making an FET with a GNR channel of the present invention.

The structure in FIG. 8A shows a substrate 820 which is made of any material on which gold (111) or any other preferred layers for growing GNRs can be deposited. Examples of substrate 820 include silicon, germanium, sapphire, or any other single crystal substrate on which gold (or other layer) grows with a preferred orientation, e.g. (111). In a preferred embodiment, there is an ultrathin release layer between the main portion of the substrate 820 and the next acene growth surface layer 815, e.g., gold. Release layers are well known and can be made of SiO2 in an ultrathin silicon-on-insulator wafer. The next layer 815 is the gold (111) layer or other preferred layers like the dimer surface reconstructed layers as described above. Layer 810 is GNR layer made as disclosed herein. Layer 805 is any know gate insulator material that can be deposited on GNRs and would be used in field effect transistors (FETs). Examples of layer 805 include insulators like SiO2, HfO2, Al2O3, or composite gate insulators in which there are first deposited a polysen layer (polyhydroxystyrene based—See Y.-M. Lin et al., Science 327, 662, (2010)). The gate layer 850 is a conductive material commonly used for FET gate electrode applications and will be patterned onto the gate insulator layer 805. The gate 850 materials are known including: copper, gold, titanium-gold, palladium, platinum, etc.

The structure in FIG. 8B further comprises a thick layer of material to act as a handle substrate 825 used to keep the structure intact during the removal of the original substrate 820. Handle layer 825 can be made from known materials including thermoset polymers.

The structure in FIG. 8C shows the original substrate 820 removed. In a preferred embodiment, the release layer is dissolved, e.g. in Hydrofluoric Acid (HF) removing the original substrate and leaving behind an ultra thin film of silicon. This thin film can be dissolved or removed by reactive ion etching (RIE.) These methods are well known.

In FIG. 8D a photoresist layer is deposited, exposed, and developed to create a source and drain electrode pattern by well known methods.

FIG. 8E shows the pattern transferred to the acene growth surface layer 815, e.g., gold by a potassium iodide KI etching that is well known to create the source 860 and drain 870 contacts.

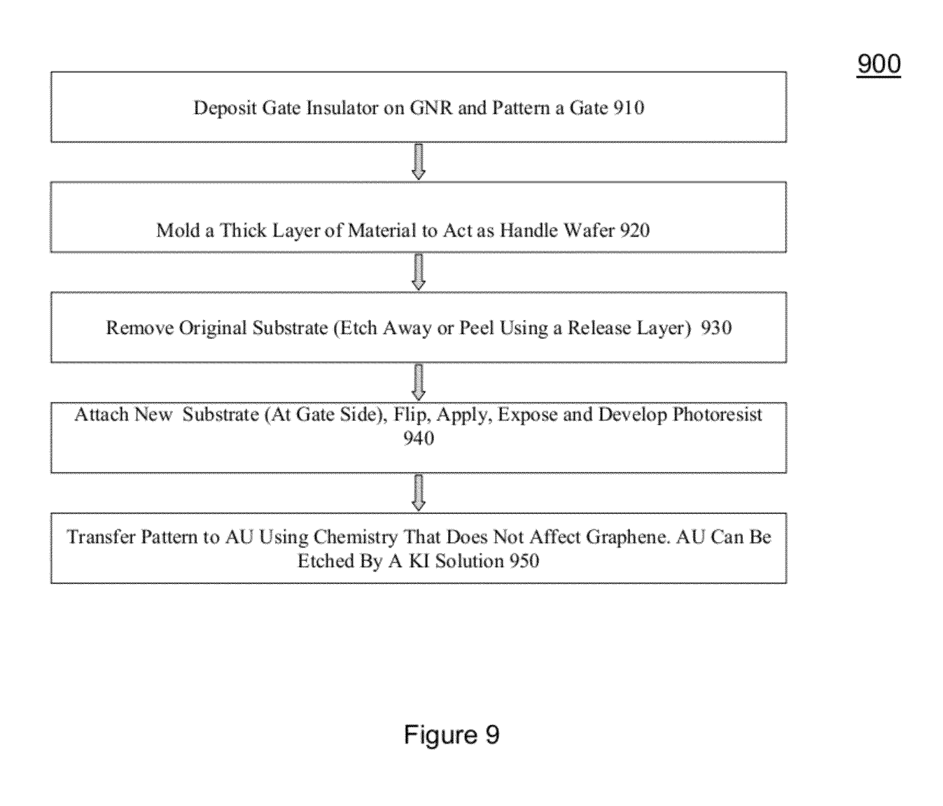

FIG. 9 discloses the steps of a process that makes an FET with a GNR channel of the present invention.

### Embodiment 1

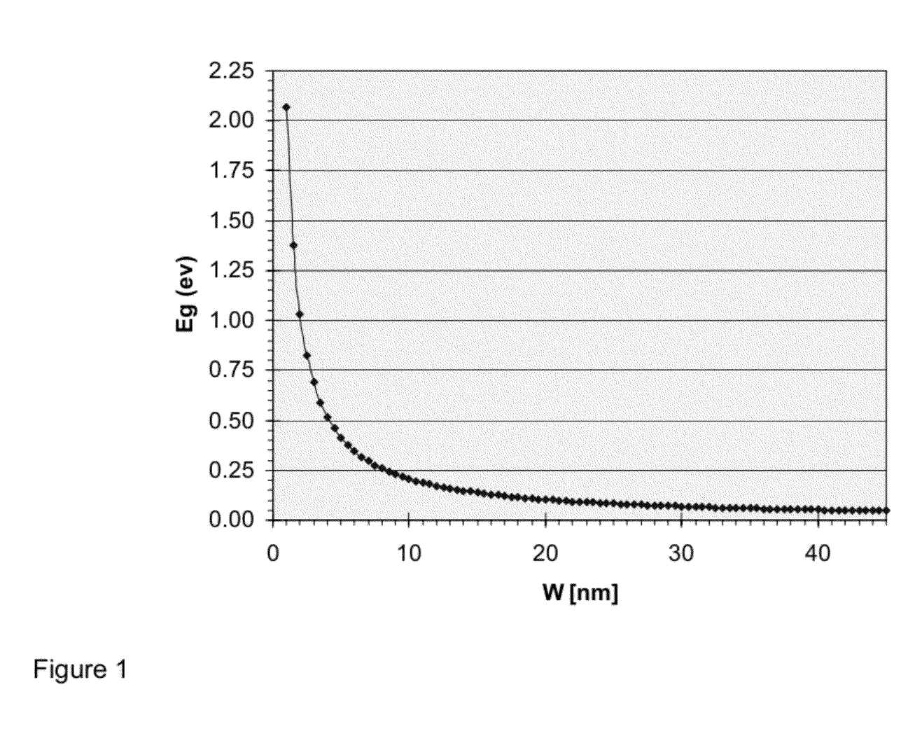

Pentacene molecules, which have a length just above 1.5 nm, can grow parallel ribbons of the same width separated by a narrow gap from a nearest neighbor (nn) ribbon on appropriate surfaces. The pentacene molecules lie with their long axis practically parallel to the surface and practically perpendicular to the direction of the strip, as shown in FIG. 1 below taken from [Käfer D. et al. Phys.Rev. B 75, 085309 (2007)]. This specific figure shows pentacene molecules self-assembled on a Au (111) surface, but other judiciously chosen surfaces could also be used to grow similar pentacene structures, preferably insulating surfaces or surfaces that could be removed later, at the device fabrication stage. Deposition of pentacene molecules can take place using a molecular beam deposition method similar to the one described in the art (Dimitrakopoulos et al. J. Appl. Phys. J. of Appl. Phys., 80, 2501-2508, (1996) “Molecular beam deposited thin films of pentacene for organic field effect transistor applications”, and Dimitrakopoulos et al. Science, 283, 822-824, (1999) “Low-voltage organic transistors on plastic comprising high-dielectric constant gate insulators”). Pentacene is placed in a resistively heated effusion cell source, and is heated under high or ultrahigh vacuum (P<1E-7 Torr or P<1E-9 Torr, respectively) to create a molecular beam of pentacene molecule. By placing the appropriate substrate surface in front of such beam, and controlling the temperature of the substrate, one can deposit a monolayer of pentacene molecules self-assembled in single-molecule rows as shown in FIG. 2. A schematic of such a pentacene single-molecule row is shown on FIG. 3.

After growth of such self-assembled pentacene single-molecule rows on an appropriate surface, an ultraviolet (UV) radiation or electron beam (e-beam) treatment should be used to make crosslinks (bonds) between the aligned nn pentacene molecules. Radiative treatments at a judiciously chosen temperature are preferred to a simple heat treatment without radiation, because pentacene will most likely evaporate before crosslinking starts by just heating between ca. 150-300° C. depending on the environment and the interaction with the substrate. After the radiation treatment at a temperature below the sublimation temperature of pentacene, some crosslinks should form randomly between neighboring molecules along the same strip (row of pentacene molecules). At that point, the large dimensions of the resulting supermolecule (made by linking many pentacene molecules together with covalent bonds) do not allow its sublimation from the substrate. FIG. 4 schematically depicts such a crosslinked pentacene supermolecular ribbon. The result of heating such a supermolecule (alternatively in combination with UV exposure) at very high temperatures in UHV or an inert atmosphere, is the creation of a complete network of aromatic bonds (stable) that are the result of decomposition (loss of hydrogen atoms) of neighboring pentacene molecular edge sites. Higher crosslinking/polymerization process temperatures may be enabled in the case of the inert atmosphere (e.g. Ar or other noble gas) vs. crosslinking/polymerization in vacuum, as sublimation of initial polymerized fragment is more difficult under an inert gas pressure. As a result of this crosslinking/polymerization process, graphene nanoribbons with width equal to pentacene length will form (such a GNR is schematically depicted in FIG. 5).

Continuation of the radiative treatment at higher temperature than the initial crosslinking process step is expected to push reaction towards the thermodynamically stable state, which would be the graphene ribbon formation, at a temperature lower that the one required for graphene nanoribbon formation by simply heating the supermolecule formed in the initial low temperature radiative step.

If the substrate surface used for the self-assembly of flat lying pentacene molecular rows is not insulating, but conductive, as is the case with the Au (111) surface used in the embodiment described above, then the graphene nanoribbons have to be transferred to an insulating substrate without disturbing their structure. This can be done by first depositing an insulating material 805 on the GNRs, e.g. depositing 10 nm of polyxydroxystyrene-based NFC that wets the graphene surfaces (spreads on them) followed by deposition of a second, thicker insulating layer of HfO₂ by atomic layer deposition (ALD), as described in prior art [see Farmer D. B et al. Nano Lett. 9, 4474, (2009)]. Then depositing a metal layer and patterning this layer to form the metal gates 850 of the prospective GNR transistors (FIG. 8A). This corresponds to step 910 in the flow-chart of FIG. 9.

Following that a thick layer of material is molded on the previous substrate to act as a handle wafer 825 (FIG. 8B). This corresponds to step 920 in the flow-chart of FIG. 9.

Then the original substrate 820, on which a Au (111) surface 815 was grown is removed (this corresponds to step 930 in the flow-chart of FIG. 9), either by etching it away, or by using a release layer (FIG. 8C).

Following that step, Au could be patterned (this corresponds to step 940 in the flow-chart of FIG. 9) to form the source and drain electrodes (860, 870) of the transistor. See FIGS. 8D and 8E. A potassium iodide (KI) etchant is used (this corresponds to step 950 in the flow-chart of FIG. 9), a process well known in the art. That leaves a graphene nanoribbon channel between these electrodes.

### Embodiment 2

The method of embodiment 1 can be used with one difference: The pentacene molecule is replaced by tetracene, an acene molecule with four fused aromatic rings instead of the five fused aromatic rings of pentacene (FIG. 7). This will result to even shorter GNRs (thus with even wider band gap) than pentacene.

### Embodiment 3

The method of embodiment 1 can be used with one difference: The pentacene molecule is replaced by anthracene, an acene molecule with three fused aromatic rings instead of the five fused aromatic rings of pentacene. This will result to even shorter GNRs (thus with even wider band gap) than tetracene.

One skilled in the art given this disclosure could envision alternative embodiments of this invention are within the contemplation of the inventor.

I claim:

1. A ribbon of graphene less than 3 nm wide.

2. A ribbon of graphene less than 1.5 nm wide.

3. A ribbon of graphene less than 1 nm wide.

4. A ribbon of graphene, as in claim 1, where the width of the ribbon is one of the following dimensions: the length of 2 phenyl rings fused together, the length of 3 phenyl rings fused together, the length of 4 phenyl rings fused together, and the length of 5 phenyl rings fused together.

5. A ribbon of graphene, as in claim 1, where the variation of thickness is less than 1 angstrom.

6. One or more ribbons of graphene, as in claim 2, where the edges of the ribbons are parallel to each other.

7. One or more ribbons of graphene with the surface of each ribbon in physical contact with a surface of a substrate.

8. One or more ribbons of graphene, as in claim 4, where the substrate is a single crystal.

9. One or more ribbons of graphene, as in claim 4, where the substrate is a single crystal and the surface of the substrate has been reconstructed to form rows with a unidirectional orientation.

10. One or more ribbons of graphene, as in claim 4, where the substrate is a non polar substrate.

11. One or more ribbons of graphene, as in claim 4, where the substrate causes the surface of is a single crystal.

12. One or more ribbons of graphene, as in claim 4, where the substrate causes a widest surface of a precursor of the graphene ribbon to become in surface to surface contact with the substrate when the precursor is placed in proximity (e.g. van der Waals bond distance) to the substrate.

13. One or more ribbons, as in claim 12, where the precursors are one or more of the following: anthracene, naphthalene, tetracene, and pentacene.

14. A ribbon of graphene less than 10 nm wide with at least one arm chair edge.

15. A ribbon of graphene, as in claim 14, less than 3 nm wide.

16. A ribbon of graphene, as in claim 14, less than 1.5 nm wide.

17. A ribbon of graphene, as in claim 14, less than 1 nm wide.

18. A ribbon of graphene, as in claim 14, where the width of the ribbon is one of the following dimensions: the length of 2 phenyl rings fused together, the length of 3 phenyl rings fused together, the length of 4 phenyl rings fused together, and the length of 5 phenyl rings fused together.

19. A ribbon of graphene, as in claim 14, where the variation of thickness is less than 1 Angstrom.

20. One or more ribbons of graphene, as in claim 16, where the edges of the ribbons are parallel to each other.

21. One or more ribbons of graphene with armchair edges and with the surface of each ribbon in physical contact with a surface of a substrate.

22. One or more ribbons of graphene, as in claim 21, where the substrate is a single crystal.

23. One or more ribbons of graphene, as in claim 21, where the substrate is a single crystal and the surface of the substrate has a directional orientation that results from a relaxation of the surface.

24. One or more ribbons of graphene, as in claim 21, where the substrate is a non polar substrate.

25. One or more ribbons of graphene, as in claim 21, where the substrate causes the surface of is a single crystal.

26. One or more ribbons of graphene, as in claim 21, where the substrate causes a widest surface of a precursor of the graphene ribbon to become in surface to surface contact with the substrate when the precursor is placed on the substrate.

27. One or more ribbons, as in claim 26, where the precursors are one or more of the following: anthracene, naphthalene, tetracene, and pentacene.

28. A Field Effect Transistor (FET) structure comprising:
a substrate;
a channel placed on the substrate having one or more nanoribbons, each nanoribbon having a width less than 10 nanometers and an armchair edge;
a gate insulator on the channel;
a gate on the gate insulator;
a source electrode on a source side of the channel; and
a drain electrode on a drain side of the channel.

29. A method of making a ribbon of graphene comprising the steps of:
a. placing one or more polyaromatic hydrocarbon (PAH) precursors on a substrate;
b. applying UV light to the PAH until one or more intermolecular bonds are formed between adjacent PAH molecules; and
c. applying heat to the PAH molecules to increase the number of intermolecular bonds that are formed to create a ribbon of graphene.

30. A method, as in claim 29, where the precursor in the acene class.

31. A method, as in claim 29, where the precursors are one or more of the following:
anthracene, naphthalene, tetracene, and pentacene.

32. A method, as in claim 29, where the UV light has a wavelength between 200 nm and 500 nm.

33. A method, as in claim 29, where the UV light has a wavelength between 290 nm and 350 nm.

34. A method, as in claim 29, where the heat applied in step 1c is provided in conjunction with the UV.

35. A method, as in claim 29, where the heat is applied in one or more of the following ways: a constant function, a step wise function, a step wise function with one or more increases in temperature, and a linearly increasing ramp of temperature.

36. A method, as in claim 29, where the substrate has a unidirectional orientation to the deposited molecules.

37. A method, as in claim 36, where the unidirectional orientation is one or more of the following: a crystalline linear orientation, a surface reconstruction, and a fabricated surface striation pattern.

38. A method as in claim 29, where the substrate is a single crystal.

39. A method, as in claim 29, where the substrate is a single crystal and the surface of the substrate has a directional orientation defined by the crystal.

40. A method, as in claim 29, where the substrate is a non polar substrate.

41. One or more ribbons of graphene, as in claim 29, where the substrate causes a widest surface of the PAH to become in surface to surface contact with the substrate when the precursor is placed on the substrate.

42. A method of making a Field Effect Transistor (FET) comprising the steps of:
creating a channel of ribbons of graphene by performing the steps of:
a. placing one or more polyaromatic hydrocarbon (PAH) precursors on a first substrate which is deposited on a second substrate;
b. applying UV light to the PAH until one or more intermolecular bonds are formed between adjacent PAH molecules; and
c. applying heat to the PAH molecules to increase the number of intermolecular bonds that are formed to create a ribbon of graphene;
depositing a gate insulator dielectric on the channel;
patterning a gate on the gate insulator dielectric;
casting a support layer on the gate to act as a handle wafer;
removing the second substrate; and
patterning the first substrate to act as a source and a drain electrode to form a field effect transistor.

43. A method, as in claim 42, where the first substrate is conductive.

44. A method, as in claim 42, where the first substrate is conductive and made of one or more of the following materials: gold, platinum, palladium, and titanium.

45. A device structure having two or more ribbons of graphene in surface to surface contact with a non conductive substrate, each of the ribbons having a width less than 3 nm and each of the ribbons having edges that are parallel to one another.

46. A three terminal device structure, as in claim 45, further comprising:
a gate conductive connection physically connected to a surface of the non conductive substrate opposite to the surface to which the ribbons contact;
a first contact electrically connected to a first end of one or more of the ribbons; and
a second contact electrically connected to a second end of one or more of the ribbons.

47. Two or more planes of ribbons of graphene, each of the planes having two or more the ribbons having a width less than 3 nm and each of the ribbons having edges that are parallel to one another, where one of the planes has ribbons of graphene in surface to surface contact with an non conductive substrate.

48. A device structure having two or more ribbons of graphene in surface to surface contact with an non conductive substrate, each of the ribbons having a width less than 3 nm and each of the ribbons having edges that are parallel to one another, the device structure having a first and second region adjacent to one another, where the first region is n type doped and the second region is p type doped.

49. A two terminal device structure, as in claim 1, further comprising:
a first contact electrically connected to the n type doped region; and
a second contact electrically connected to the p type doped region.
